(19) United States
(12) Patent Application Publication
(10) Pub. No.: US 2003/0060041 A1
(43) Pub. Date: Mar. 27, 2003

(54) Dual-stack, ball-limiting metallurgy and method of making same

(75) Inventors: Madhav Datta, Portland, OR (US); Dave Emory, Aloha, OR (US); Subhash M. Joshi, Beaverton, OR (US); Susanne Menezes, Portland, OR (US); Doowon Suh, Warren, OR (US)

Correspondence Address: Schwegman, Lundberg, Woessner & Kluth, P.A., P.O. Box 2938, Minneapolis, MN, 55402, US

(73) Assignee: Intel Corporation

(21) Appl. No.: 09/961,036

(22) Filed: Sep. 21, 2001

(51) Int. Cl. H01L 21/44

(52) U.S. Cl. 438/652

(57) ABSTRACT

The invention relates to a ball-limiting metallurgy (BLM) stack for an electrical device. The dual BLM stack resists tin migration toward the upper metallization of the device.

### FIELD OF THE INVENTION

The present invention relates generally to integrated circuit fabrication. More particularly, the present invention relates to electrical connection technology. In particular, the present invention relates to a ball-limiting metallurgy.

### BACKGROUND OF THE INVENTION

### Description of Related Art

Electrical bump connectors such as metal bumps or balls are used in flip-chip (C4) applications. As the progress of miniaturization continues, the sizes of individual metal grains in the junction between a microelectronic device metallization and the electrical bump become increasingly problematic relative to the mass of the electrical bump. Consequently, junction disparities have an increasingly detrimental effect on electrical communication between the device and the electrical bump. For example, the grain size of metal in the metal bump does not miniaturize. One junction disparity relates to migration of bump metals through the metal layer that is disposed over the metallurgy.

### BRIEF DESCRIPTION OF THE DRAWINGS

In order that the manner in which the embodiments of the invention are obtained, a more particular description of the invention briefly described above will be rendered by reference to specific embodiments thereof which are illustrated in the appended drawings. Understanding that these drawings depict only typical embodiments of the invention that are not necessarily drawn to scale and are not therefore to be considered to be limiting of its scope, the invention will be described and explained with additional specificity and detail through the use of the accompanying drawings in which:

FIG. 1 is an elevational cross-section of a semiconductor structure that reveals metallization;

FIG. 2 is an elevational cross-section of the semiconductor structure depicted in FIG. 1 after patterning of a passivation layer;

FIG. 3 is an elevational cross-section of the semiconductor structure depicted in FIG. 2 after further processing;

FIG. 4 is an elevational cross-section of the semiconductor structure depicted in FIG. 3 after further processing;

FIG. 5 is an elevational cross-section of the semiconductor structure depicted in FIG. 4 after further processing;

FIG. 6 is an elevational cross-section of the semiconductor structure depicted in FIG. 5 after further processing;

FIG. 7 is an elevational cross-section of the semiconductor structure depicted in FIG. 6 after further processing;

FIG. 8A is an elevational cross-section of the semiconductor structure depicted in FIG. 7 after further processing;

FIG. 8B is an elevational cross-section of the semiconductor structure depicted in FIG. 7 after further processing according to an alternative process flow;

FIG. 8C is an elevational cross-section of the semiconductor structure depicted in FIG. 8A after further processing;

FIG. 9 is an elevational cross-section of the semiconductor structure depicted in FIG. 8 after further processing; and

FIG. 10 is a flow chart that describes a process embodiment.

### DETAILED DESCRIPTION OF THE INVENTION

The present invention relates to a ball-limiting metallurgy (BLM) stack that facilitates miniaturization and that resists electrical discontinuities between metallization and metal bumps. In one embodiment, a metal first layer is disposed above and on the metallization. A metal second layer is disposed over the metal first layer, and a metal third layer that is the same composition as the metal first layer, is disposed over the metal second layer. Similarly, a metal fourth layer, that is the same composition as the metal second layer, is disposed over the metal third layer.

The following description includes terms, such as upper, lower, first, second, etc. that are used for descriptive purposes only and are not to be construed as limiting. The embodiments of an apparatus or article of the present invention described herein can be manufactured, used, or shipped in a number of positions and orientations.

Reference will now be made to the drawings wherein like structures will be provided with like reference designations. In order to show the structures of the present invention most clearly, the drawings included herein are diagrammatic representations of integrated circuit structures. Thus, the actual appearance of the fabricated structures, for example in a photomicrograph, may appear different while still incorporating the essential structures of the present invention. Moreover, the drawings show only the structures necessary to understand the present invention. Additional structures known in the art have not been included to maintain the clarity of the drawings.

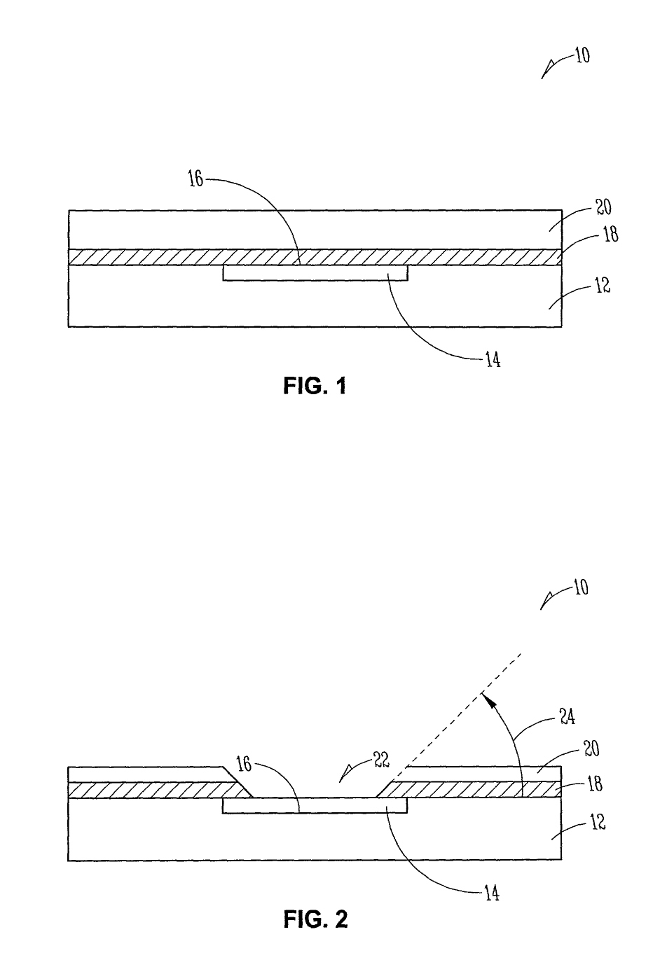

FIG. 1 is a cross-section of a semiconductor structure 10 during fabrication that includes a substrate 12 and a metallization 14 such as a copper pad that makes connection to what is commonly referred to as metal six (M6) by way of non-limiting example. Metallization 14 may be disposed upon an upper surface 16 of substrate 12 where substrate 12 may be an interlayer dielectric (ILD) composition. A nitride layer 18 is formed over substrate 12, and a passivation layer 20 is formed over nitride layer 18, substrate 12, and metallization 14. Passivation layer 20 and nitride layer 18 act to protect substrate 12 and to expose metallization 14 according to the patterning. Passivation layer 20 may be a polyimide material or it may be an inorganic material such as a silicon oxide that is formed by the decomposition of tetraethyl ortho silicate (TEOS). Patterning is accomplished by a first mask (not pictured) that exposes passivation layer 20 through a recess 22 during an etch process.

FIG. 2 illustrates a patterned passivation structure, that includes portions of former nitride layer 18 and passivation layer 20, and that exposes a portion of metallization 14. The process may be carried out by blanket forming nitride layer 18 and passivation layer 20, patterning, etching recess 22, and curing passivation layer 20 where passivation layer 20 is a polyimide. After the cure, passivation layer 20 has formed a slope 24 that may have an angle, in a range from about 30° to about 60°, and preferably about 45°.

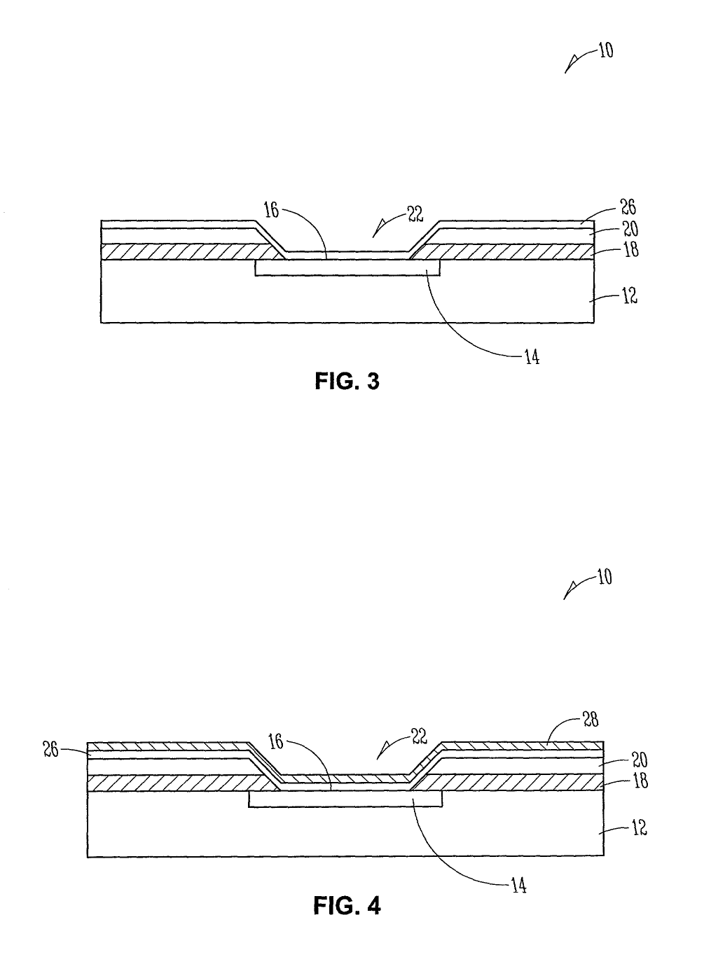

FIG. 3 illustrates further processing that is carried out where the patterned passivation layer 20, nitride layer 18, and metallization 14 are covered with a metal first layer 26. Metal first layer 26 may be a refractory metal such as titanium, zirconium, hafnium, and the like. Other refractory metals for metal first layer 26 may include nickel, cobalt, palladium, platinum, and the like. Other refractory metals for metal first layer 26 may include chromium, molybdenum, tungsten, and the like. Other refractory metals for metal first layer 26 may include scandium, yttrium, lanthanum, cerium, and the like. One preferred property embodiment may be a metal first layer that exhibits sufficient adhesion to the metallization that liftoff or spalling thereof will not occur during fabrication, test, and ordinary field use.

In one embodiment, metal first layer 26 is titanium that is formed by physical vapor deposition (PVD) to a thickness in a range from about 500 Å to about 2,000 Å, and preferably about 1,000 Å. In another embodiment, metal first layer 26 is chromium that is formed by physical vapor deposition (PVD) to a thickness in a range from about 500 Å to about 2,000 Å, and preferably about 1,000 Å.

FIG. 4 illustrates further processing in which metal first layer 26 is covered with a metal second layer 28. Metal second layer 28 may preferably be a refractory metal, a refractory metal alloy, or a doped refractory metal. The alloy or the doped metal may be in stoichiometric or solid solution ratios. In one embodiment, metal second layer 28 is a vanadium-alloyed or vanadium-doped metal of at least one metal selected from nickel, cobalt, palladium, platinum, and the like. The vanadium may be added where the refractory metal may be ferroelectric. In one embodiment, metal second layer 28 is a metal, a vanadium-alloyed, or vanadium-doped metal of at least one selected from titanium, zirconium, hafnium, and the like. In another embodiment, metal second layer 28 is a metal, a vanadium-alloyed, or vanadium-doped metal of at least one selected from chromium, molybdenum, tungsten, and the like. In another embodiment, metal second layer 28 is a metal, a vanadium-alloyed, or vanadium-doped metal of at least one selected from scandium, yttrium, lanthanum, cerium, and the like.

In one embodiment, metal second layer 28 is a metal, a metal-vanadium alloy, or vanadium-doped nickel metal that is formed by PVD to a thickness in a range from about 1,000 Å to about 4,000 Å, and preferably about 2,000 Å. In one embodiment, metal second layer 28 is a NiV alloy. In another embodiment, metal second layer 28 is a vanadium-doped nickel layer.

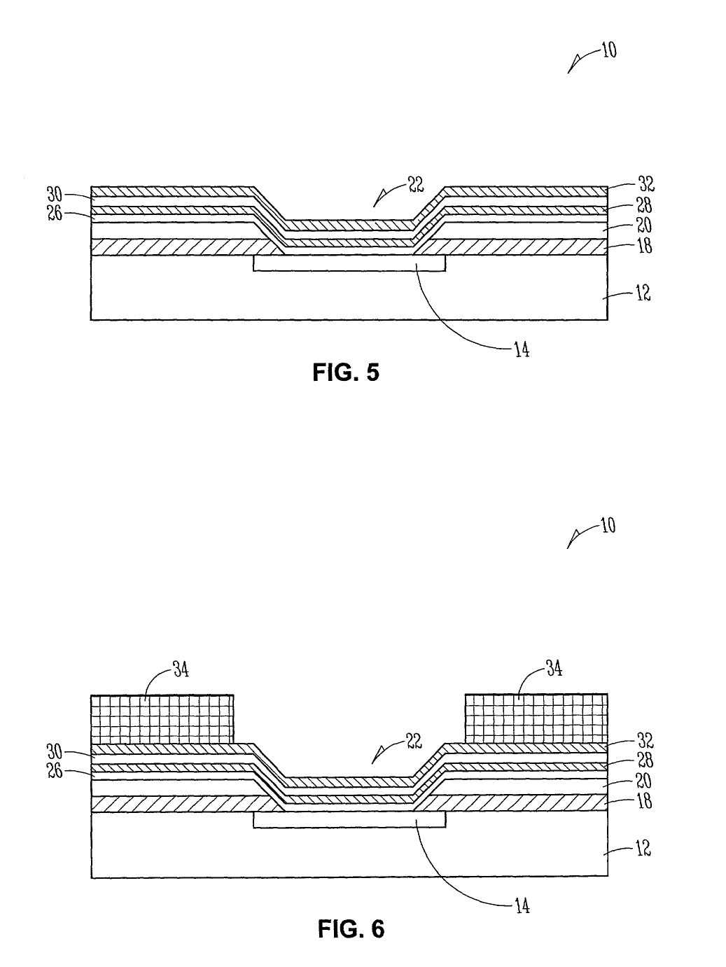

FIG. 5 illustrates further processing in which a metal third layer 30 and a metal fourth layer 32 are formed over substrate 12. Metal third layer 30 may be substantially the same composition as metal first layer 26, within usual process variations, and metal fourth layer 32 is substantially the same composition as metal second layer 28, also within usual process variations. Alternatively, metal third layer 30 may be substantially the same metal type as metal first layer 26 according to grouping as set forth herein. Similarly, metal fourth layer 32 may be substantially the same metal type as metal second layer 28 according to grouping as set forth herein. Accordingly, “substantially the same metal” or “substantially the same composition” may be referred to as substantially the same metal type according to grouping as set forth herein. In one embodiment, metal first and third layers 26, 30 are Ti, and metal second and fourth layers 28, 32 are Ni. Sputtering of metal first through fourth layers 26-32 may be carried out in order to have them, or one or more of them, to carry a compressive stress that will resist liftoff from patterned passivation layer 20 and from metallization 14. Such processing conditions are known in the art.

Although sputtering of metal first through fourth layers 26-32 may be a preferred embodiment, evaporation deposition of a material such as an organometallic material may also be used as is known in the art.

In another embodiment, metal first and third layers 26, 30, have thicknesses in arbitrary units in a range from about 500 to about 2,000, preferably about 1,000. Similarly, metal second and fourth layers 28, 32, have thicknesses in arbitrary units in a range from about 1,000 to about 4,000, preferably about 2,000. As miniaturization technology progresses the ratios of metal first and third- and metal second and fourth layers may be formed according to these proportionalities.

In an alternative embodiment, metal second layer 28 and metal fourth layer 32, or one of them, is nitrided to form a nitrided metal alloy or a nitrided vanadium-doped metal as set forth herein. Nitriding conditions may be carried out according to known technique for nitridation of metals. In selected embodiments, metal second layer 28 and metal fourth layer 32 are nitrided refractory metal-vanadium alloys or nitrided, vanadium-doped refractory metals. In other selected embodiments, metal second layer 28 and metal fourth layer 32 are nitrided NiV alloys or nitrided vanadium-doped nickel.

Following the formation of the four metal layers 26-32 as set forth herein, processing may continue by plating a bump precursor over the four-metal-layer stack. Plating may be electroless plating or preferably electroplating as is known in the art.

FIG. 6 illustrates further processing in which a second mask 34 is patterned to expose metal fourth layer 32 centered over metallization 14. Second mask 34 is peripherally patterned because a plating process is carried out to plate a bump precursor that adheres to metal fourth layer 32.

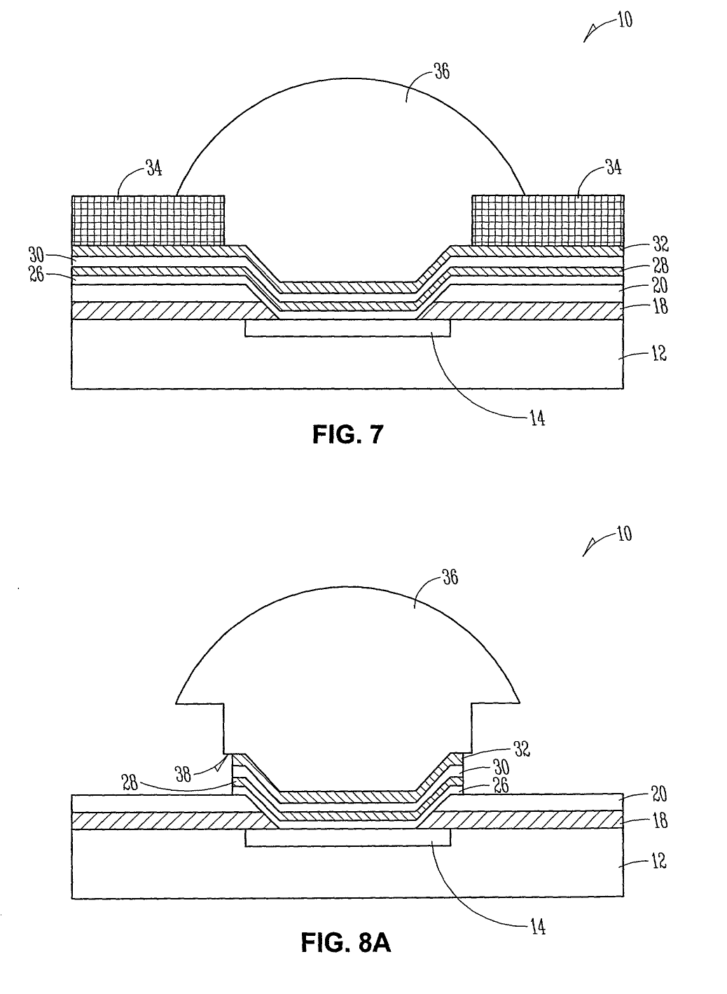

FIG. 7 illustrates further processing in which a bump precursor button 36 has been plated over metal fourth layer 32 through second mask 34. Plating may be carried out by electroless plating techniques or by electroplating techniques as is known in the art. Preferably, by way of non-limiting example, plating is carried out to form bump precursor button 36 as a discrete structure that is spaced-apart from any closest neighboring bump precursors. Accordingly, bump precursor button 36 may have a curvilinear perimeter (not pictured) and a curvilinear vertical profile. Alternatively, a plating film may be formed and subsequently patterned into substantially discrete bump precursor structures by a process such as an etch. Accordingly, the bump precursor structure may have a rectilinear perimeter (not pictured) and a rectilinear vertical profile (also not pictured). In any event, bump precursor button 36 or a patterned bump precursor structure (not depicted) may be selected from a solder composition that facilitates embodiments.

Bump precursor button 36 may be a tin-lead solder. In selected embodiments, bump precursor button 36 is a tin-lead solder composition selected from Sn97Pb, and SnₓPb_{y}, wherein x+y total 1, and wherein x is in a range from about 0.3 to about 0.99. Where C4 processing is carried out, the solder bump of the flip chip may have a solder composition of Sn37Pb or the like.

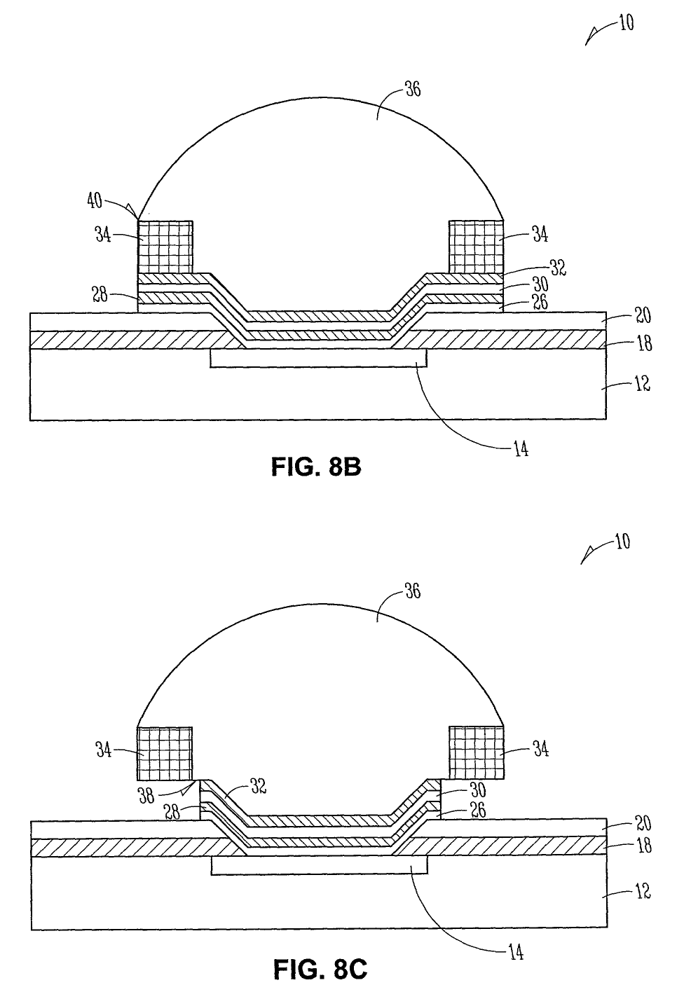

FIG. 8A illustrates further processing in which the four metal layers 28-32 are removed substantially everywhere except directly under bump precursor button 36. Second mask 34 may be simultaneously removed, or it may be preliminarily removed such as by ashing or wet stripping. Removal of the four metal layers may be carried out by a wet etch that is substantially selective to the electrically conductive bump precursor button 36, and to passivation layer 20. Although some undercutting 38 into the four metal layers 26-32 beneath bump precursor button 36 may be desirable, it may be balanced against risking a total slumping of the solder during reflow. In one embodiment, undercutting 38 may be in a range from about 0.5 micrometers (microns) to about 6 microns, preferably about 3 microns.

Alternatively, second mask 34 may be removed by any means such as ashing or wet stripping, and a multi-process etch may be carried out to remove lateral portions of the four metal layers 26-32 as depicted in FIG. 8B. In a first process, an anisotropic etch is carried out where bump precursor button 36, out to the tip 40 thereof, acts as a shadow mask. FIG. 8B illustrates shadow mask etching wherein second mask 34 is removed except where it is shadow-protected by tip 40 of bump precursor button 36. Similarly, removal of the metal layers 28-32 has occurred except where bump precursor button 36 acts as a shadow mask. Next, second mask 34 is wet stripped. Thereafter, a wet etch is carried out to remove excess metal layer material to achieve a structure similar to what is depicted in FIG. 8. Alternatively, the wet etch may be configured to simultaneously remove second mask 34.

In a third alternative, processing is carried out similar to what is depicted as being processed in FIG. 8C. After the anisotropic etch of both second mask 34 and some of the metal layers 26-32 is completed as set forth herein, an isotropic wet etch is carried out. The anisotropic wet etch laterally etches the metal layers 26-32 to form metal layers 26-32 similar to what is depicted in FIG. 8A. The etch recipe is selective to various structures; passivation layer 20, what is left of second mask 34 by the shadow-mask effect of bump precursor button 36, and bump precursor button 36 itself are substantially not etched. Thereafter, ashing or another removal technique known in the art is carried out to remove what is left of second mask 34. Thereby, undercutting 38 of the metal layers 26-32 is controlled by the presence of what is left of second mask 34.

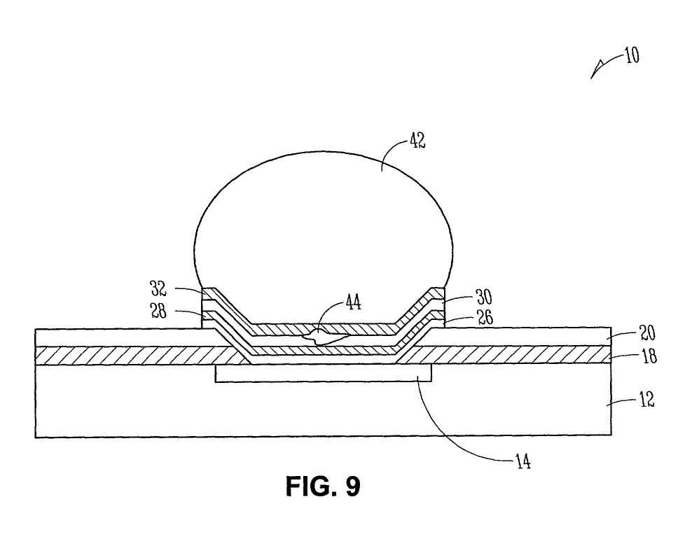

FIG. 9 illustrates further processing in which the bump precursor button 36 has been reflowed into a solder ball 42 that has been dimensionally limited by the metallurgy of the metal layers 26-32 and by the degree of undercutting 38 as set forth herein. Hence the BLM of an embodiment may cause sufficient wetting of solder ball 42 onto metal fourth layer 32 to form a solder ball 42 that has a preferred shape and height. In selected embodiments, the vertically measured diameter of solder ball 42 may be in a range from about 50 micrometers (microns) to about 200 microns. In another embodiment, the diameter of bump precursor button 36 is about 57 microns before it is reflowed, and it is about 100 microns after it is reflowed.

The eccentricity (the vertical diameter divided by the horizontal diameter) of solder ball 40 may be in a range from about 0.5 to about 1.2. A lower eccentricity may be preferred where the pitch of a given ball array would lead to a bridging problem between neighboring balls during reflow or during reflow flip-chip mounting. Eccentricity may be controlled by solder ball amount and solder ball wetting properties in relation to metal fourth layer 32.

Because some intermetallic material may form between the solder ball 42 and metallization 14, the metal layers 26-32 act to prevent excessive intermetallic formation, and to resist tin migration toward metallization 14. FIG. 9 illustrates an intermetallic zone 44, in an arbitrary shape and size, that may form under ordinary processing conditions according to an embodiment. Where the solder ball metallurgy is SnₓN_{y} or the like, a nickel-tin intermetallic zone 44 may form that may be restricted by the BLM configuration according to embodiments set forth herein. In one embodiment, certain thicknesses of first-through-fourth layers 26-32 are preferred to form intermetallic material. The metal layers should not be too thin individually so that the BLM stack is consumed. Otherwise, during the temperature cycling, once the BLM stack is consumed, now the intermetallic that forms, segregates and form shapes that may move upwards into the solder. Consequently, volume changes that correspond with intermetallic formation may cause significant stress in the electrical structure.

The following is an example of a process flow embodiment. Reference may be made to FIGS. 1-9. A substrate 12 containing an M6 metallization and a metallization 14 bond pad is provided. Substrate 12 contains a silicon oxide ILD material as is known in the art. A nitride layer 18 and a passivation layer 20 is formed over substrate 12 and metallization 14. Passivation layer 20 is a polyimide layer that is formed according to known technique, and that, upon curing, shrinks and forms an angle 24 of about 45°. Thereafter, a first mask (not pictured) is spun on and patterned to expose a recess 22. Etching of passivation layer 18 is carried out in a dry etch that segments passivation layer 18 into a patterned passivation layer 24.

A metal first layer 26 is formed by PVD of Ti over substrate 12 and structures supported thereon. Next, a metal second layer 28 is formed by PVD of a NiV alloy over metal first layer 26. Metal second layer 28 is nitrided by a thermal treatment thereof according to known technique. A metal third layer 30 is formed by PVD of Ti over metal second layer 30. Metal third layer 30 may be sputtered from the same Ti sputtering target used to form metal first layer 26. Finally as to forming metal layers, a metal fourth layer 32 is formed by PVD of a NiV alloy over metal second layer. Metal fourth layer 32 may be sputtered from the same NiV sputtering target used to form metal second layer 28. Nitriding of metal fourth layer 32 is carried out under substantially the same conditions that were used to nitride metal second layer 28.

After the formation of the four metal layers 26-32, a second mask 34 is spun on, cured, exposed, and patterned according to known technique. Patterning of second mask 34 exposes metal fourth layer 32 directly above metallization 14. Thereafter, an electroplating solution that has tin and lead in a Sn97Pb proportion is applied over substrate 12 until a bump precursor button 36 has been formed. Next, an anisotropic etch is carried out that removes portions of second mask 34 and that stops on metal fourth layer 32. A follow-up anisotropic etch is carried out that removes lateral portions of the four metal layers according to the shadow-mask technique set forth herein. Finally, a wet third etch is carried out that undercuts 38 the remaining portions of second mask 34 until a preferred dimension of a BLM stack of the four metal layers 26-32 remains. Second mask 34 is removed by a wet stripping process. Thereafter, a thermal process acts that reflows bump precursor button 36 to form a solder ball 42. The formation of some intermetallic zone 44 is incidental.

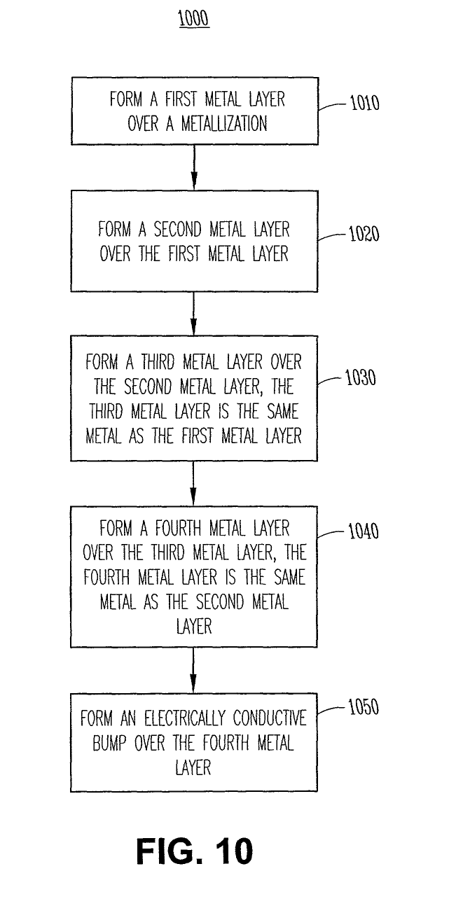

FIG. 10 is a process flow diagram of an embodiment. The process 1000 includes forming 1010 a metal first layer over a metallization as set forth herein. Processing continues by forming 1020 a metal second layer over the metal first layer. As set forth herein, a metal third layer is formed 1030 over the metal second layer, and the metal third layer is the same metal or type as the metal first layer. Thereafter, a metal fourth layer is formed 1040 over the metal third layer. Similarly, the metal fourth layer is the same metal or type as the metal second layer. Finally, an electrically conductive bump is formed 1050 as set forth herein.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

5. The BLM stack according to claim 1, wherein the metal second layer comprises a nitrided refractory metal or a nitrided metal alloy.

6. The BLM stack according to claim 1, wherein the metal second layer comprises a nitrided refractory metal or nitrided refractory metal alloy selected from Ni, Co, Pd, Pt, NiV, CoV, PdV, PtV, Ti, Zr, Hf, Cr, Mo, W, Sc, Y, La, and Ce in a solid-solution or stoichiometric ratio.

7. The BLM stack according to claim 1, further comprising:
an intermetallic zone disposed between the metal fourth layer and the electrically conductive bump.

8. The BLM stack according to claim 1, further comprising:
an intermetallic zone disposed between the metal fourth layer and the electrically conductive bump, wherein the intermetallic zone comprises a Sn-refractory metal composition.

9. The BLM stack according to claim 1, wherein the electrically conductive bump comprises a tin-lead solder composition.

10. The BLM stack according to claim 1, wherein the electrically conductive bump comprises a tin-lead solder composition selected from Sn37Pb, Sn97Pb, and SnₓPb_{y}, wherein x+y total 1 and wherein x is in a range from about 0.3 to about 0.99.

11. A ball-limiting metallurgy (BLM) stack comprising:
a refractory metal first layer disposed over a metallization, wherein the refractory metal first layer is in a thickness range from about 500 to 2,000 length units;
a refractory metal second layer disposed over the refractory metal first layer, wherein the refractory metal second layer is in a thickness range from about from about 1,000 to about 4,000 of said length units;
a refractory metal third layer disposed over the refractory metal second layer, wherein the refractory metal third layer is in a thickness range from about from about 500 to 2,000 of said length units, and wherein the metal third layer is substantially the same composition as the refractory metal first layer;
a refractory metal fourth layer disposed over the refractory metal third layer, wherein the refractory metal fourth layer is in a thickness range from about from about 1,000 to about 4,000 of said length units, and wherein the refractory metal fourth layer is substantially the same composition as the refractory metal second layer; and
an electrically conductive bump disposed over the refractory metal fourth layer.

12. The BLM stack according to claim 11, wherein the refractory metal first and third layers comprise Ti.

13. The BLM stack according to claim 11, wherein the refractory metal first and third layers comprise Ti and the refractory metal first and third layers have a thickness of about 1,000 Å.

14. The BLM stack according to claim 11, wherein the refractory metal first and third layers comprise Ti and the refractory metal first and third layers each have a thickness of about 1,000 Å, and wherein the refractory metal second and fourth layers each have a thickness of about 2,000 Å.

15. The BLM stack according to claim 11, further comprising:
an intermetallic zone disposed between the metallization and the electrically conductive bump, wherein the intermetallic zone comprises a Sn-refractory metal composition.

16. The BLM stack according to claim B11, further comprising:
an intermetallic zone disposed between the metallization and the electrically connective bump.

17. A process comprising:
forming a metallization;
forming a refractory metal first layer over the metallization;
forming a refractory metal second layer over the refractory metal first layer;
forming a refractory metal third layer above and on the refractory metal second layer, wherein the third refractory metal is substantially the same metal as the refractory metal first layer;
forming a refractory metal fourth layer above and on the refractory metal third layer, wherein the refractory metal fourth layer is substantially the same metal as the refractory metal first layer; and
forming an electrically connective bump above the refractory metal fourth layer.

18. The process according to claim 17, wherein forming a metallization comprises:
forming a copper metallization pad over a substrate, wherein the copper metallization pad makes contact with a metallization selected from a range of metal-one (M1) to M6.

19. The process according to claim 17, wherein forming a refractory metal first layer over the metallization comprises:
depositing the refractory metal first layer by physical vapor deposition of a composition selected from Ni, Co, Pd, Pt, Ti, Zr, Hf, Cr, Mo, W, Sc, Y, La, and Ce.

20. The process according to claim 17, wherein forming a refractory metal first layer over the metallization comprises:
sputtering Ti over the metallization to a thickness in a range from about 500 Å to about 2,000 Å.

21. The process according to claim 17, wherein forming a refractory metal second layer over the refractory metal first layer comprises:
depositing the refractory metal second layer by physical vapor deposition of a composition selected from Ni, Co, Pd, Pt, NiV, CoV, PdV, PtV, Ti, Zr, Hf, Cr, Mo, W, Sc, Y, La, and Ce in a solid-solution or stoichiometric ratio.

22. The process according to claim 17, wherein forming a refractory metal second layer over the refractory metal first layer comprises:
sputtering NiV over the refractory metal first layer to a thickness in a range from about 1,000 Å to about 4,000 Å.

23. The process according to claim 17, wherein forming a refractory metal third layer over the metallization comprises:
depositing the refractory metal third layer by physical vapor deposition.

24. The process according to claim 17, wherein forming a refractory metal third layer over the metallization comprises:
sputtering NiV over the refractory metal second layer to a thickness in a range from about 500 Å to about 2,000 Å.

25. The process according to claim 17, wherein forming a refractory metal fourth layer over the refractory metal first layer comprises:
depositing the refractory metal fourth layer by physical vapor deposition.

26. The process according to claim 17, wherein forming a refractory metal fourth layer over the refractory metal first layer comprises:
sputtering NiV over the refractory metal third layer to a thickness in a range from about 1,000 Å to about 4,000 Å.

27. A process comprising:
forming a metallization;
sputtering a refractory metal first layer over the metallization;
sputtering a refractory metal second layer over the refractory metal first layer, wherein the refractory metal second layer is a refractory metal alloy;
sputtering a refractory metal third layer above and on the refractory metal second layer, wherein the third refractory metal is substantially the same metal as the refractory metal first layer;
sputtering a refractory metal fourth layer above and on the refractory metal third layer, wherein the refractory metal fourth layer is substantially the same metal as the refractory metal first layer; and
plating a Sn-containing solder through a mask onto the refractory metal fourth layer to form an electrically connective bump.

28. The process according to claim 27, further comprising:
etching the first-through-fourth refractory metal layers with an etch recipe that is selective to the solder; and
reflowing the solder.

29. The process according to claim 27, further comprising
first anisotropic etching the first-through-fourth refractory metal layers with an etch recipe that is selective to the solder;
second isotropic etching the first-through-fourth refractory metal layers with an etch recipe that is selective to the solder and to the mask; and
reflowing the solder.

30. The process according to claim 27, further comprising:
anisotropically etching the mask and the first-through-fourth refractory metal layers by using the bump precursor as a shadow mask; and
etching the first-through-fourth refractory metal layers with an etch recipe that is selective to the solder.
